(19) United States
(12) Patent Application Publication
(10) Pub. No.: US 2015/0028754 A1
(43) Pub. Date: Jan. 29, 2015

(54) ZERO ENERGY STORAGE DRIVER INTEGRATED IN LED CHIP CARRIER

(71) Applicant: OSRAM SYLVANIA Inc., Danvers, MA (US)

(72) Inventors: Bernhard Siessegger, Danvers, MA (US); Norwin von Malm, Thumhausen (DE); Phil Moskowitz, Goergetown, MA (US); Warren Moskowitz, Ipswich, MA (US)

(73) Assignee: OSRAM SYLVANIA Inc., Danvers, MA (US)

(21) Appl. No.: 14/373,063

(22) PCT Filed: Jan. 21, 2013
(86) PCT No.: PCT/US13/22390

§ 371 Date: Jul. 18, 2014

Related U.S. Application Data
(60) Provisional application No. 61/588,838, filed on Jan. 20, 2012.

(51) Int. Cl. H05B 33/08; H01L 33/62; H01L 27/15

(52) U.S. Cl. CPC H05B 33/0827; H05B 33/0851; H01L 27/156; H01L 33/62
USPC 315/186

(57) ABSTRACT

LED devices are provided that include LED chips on LED chip carriers. The LED device can in turn be housed in a package, such as a small-outline transistor (SOT) package or a radial LED device package. A single LED device or a serial connection of a plurality of such LED devices can be operated directly from an AC (line) voltage or a rectified version thereof. In some example embodiments, switching circuitry is integrated into the LED chip carrier for controlling current flow through the LED(s) in response to, for example, a brightness regulating control signal. Numerous example embodiments of the monolithic LED devices are provided, including manufacturing processes as well as various example packages for such LED devices.

### RELATED APPLICATIONS

This application claims priority to U.S. Provisional Application No. 61/588,838, filed Jan. 20, 2012. In addition, this application is a continuation-in-part of U.S. application Ser. No. 13/229,611, filed Sep. 9, 2011. Each of these applications is herein incorporated by reference in its entirety.

### FIELD OF THE DISCLOSURE

The present application relates to lighting systems, and more specifically to an LED device configured with integrated driver circuitry so as to provide a monolithic lighting system.

### BACKGROUND

Light emitting diodes (LEDs) and driving circuits are manufactured separately and electrically connected afterwards to provide a given lighting system. Simple and cheap drivers for series connection of LEDs are known that consist of a bridge rectifier and a filtering capacitor in parallel to the LED string. Optionally, a linear resistance controller in series to the LED string may be added.

### BRIEF DESCRIPTION OF THE DRAWINGS

FIG. 1a schematically illustrates a zero energy storage (ZES) LED driver that can be used in accordance with an embodiment of the present invention.

FIG. 1b illustrates a block diagram of an example control circuit that can be used in the ZES LED driver, in accordance with an embodiment of the present invention.

FIG. 2 schematically illustrates a zero energy storage (ZES) driver integrated in an LED chip carrier, in accordance with an embodiment of the present invention.

FIG. 3 schematically illustrates a ZES-driver integrated in an LED chip carrier, in accordance with another embodiment of the present invention.

FIG. 4 schematically illustrates a ZES-driver integrated in an LED chip carrier, in accordance with another embodiment of the present invention.

FIG. 5 schematically illustrates a system configured with multiple LED chips configured with integrated ZES-drivers, in accordance with an embodiment of the present invention.

FIG. 6a illustrates some example pixel shapes and FIGS. 6b-6e each illustrates an example lateral arrangement of pixels that can be implemented in a ZES-driver integrated in an LED chip carrier, in accordance with an embodiment of the present invention.

FIG. 7 schematically illustrates a ZES-driver integrated in an LED chip carrier, in accordance with another embodiment of the present invention.

FIG. 8 schematically illustrates a ZES-driver integrated in an LED chip carrier, in accordance with another embodiment of the present invention.

FIG. 9 schematically illustrates a ZES-driver integrated in an LED chip carrier, in accordance with another embodiment of the present invention.

FIG. 10a illustrates a cross-section side view of an LED device configured with an integrated ZES-driver, in accordance with an embodiment of the present invention.

FIG. 10b illustrates a cross-sectional side view of an LED device configured with an integrated ZES-driver, in accordance with another embodiment of the present invention.

FIG. 11 illustrates a side view of an LED device configured with an integrated ZES-driver, in accordance with another embodiment of the present invention.

FIG. 12 schematically illustrates a ZES-driver integrated in an LED chip carrier, in accordance with another embodiment of the present invention.

FIG. 13 schematically illustrates a ZES-driver integrated in an LED chip carrier, in accordance with another embodiment of the present invention.

FIG. 14 illustrates a cross-sectional side view of an LED device configured with an integrated ZES-driver, in accordance with another embodiment of the present invention.

FIG. 15 illustrates a ZES circuit topology susceptible to significant brightness difference between the pixels at the beginning of the LED string compared to the end of the LED string, assuming identical pixels and numbers of pixels per group.

FIG. 16 schematically illustrates a system configured with multiple LED chips configured with integrated ZES-drivers, in accordance with another embodiment of the present invention.

### DETAILED DESCRIPTION

LED devices are provided that include LED chips on LED chip carriers. The LED device can in turn be housed in a package, such as a small-outline transistor (SOT) package or a radial LED device package. A single LED device or a serial connection of a plurality of such LED devices can be operated directly from an AC (line) voltage or a rectified version thereof. In some example embodiments, switching circuitry is integrated into the LED chip carrier for controlling current flow through the LED(s) in response to, for example, a brightness regulating control signal. Numerous example embodiments of the monolithic LED devices are provided, including manufacturing processes as well as various example packages for such LED devices.

General Overview

As previously noted, LEDs and driving circuits are manufactured separately and electrically connected afterwards. The functionality of the rectifier can be integrated to the LED chip by an intra-chip anti-parallel connection of several semiconductor segments or the connection of such segments like a bridge rectifier. However, such configurations have the disadvantage that the resulting light source flickers strongly (half-wave rectifier; 50 or 60 Hz light modulation) and/or exhibits strong effects of strobing (sometimes also misleadingly called flickering) because light emission takes place in a short period of the half wave solely. The input current waveform appears disadvantageous as well, as the current drawn from the line basically looks like a repetitive sequence of spikes; each half-cycle a spike occurs around the crest of the line voltage. Apart from that, the LEDs are driven under unfavorable conditions for most of the time.

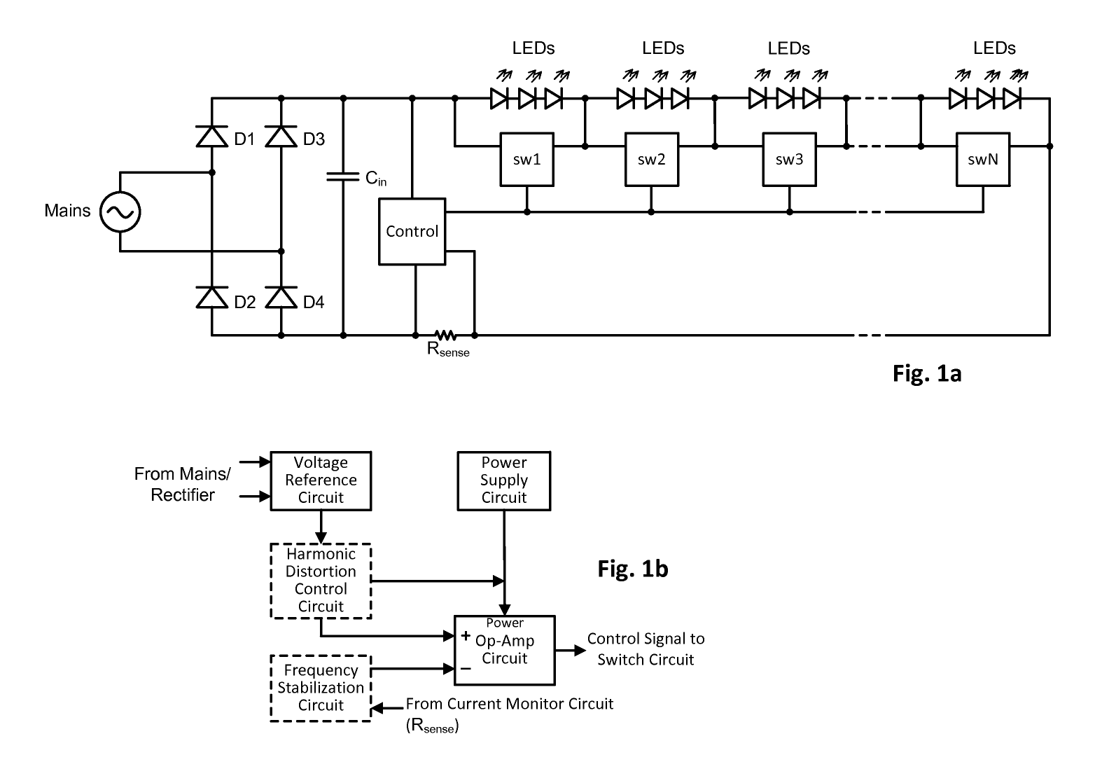

A driving circuit for LED strings that can be used to overcome these issues in accordance with an embodiment of the present invention is illustrated in FIG. 1a. As can be seen in this example embodiment, a string of LEDs (a series connection of LEDs) is subdivided into N groups (a group can include a single LED or a bank of LEDs connected in series and/or parallel; the example shown includes three serially connected LEDs per group). The groups are shorted by parallel connected controllable switches sw1, sw2, . . . , swN, which can be implemented with transistor-based or other suitable switching technology. As can be further seen, the switches are responsive to a control circuit, which is configured to sense the current (via Rₛₑₙₛₑ) flowing through the LEDs and to control the switches depending on the actual voltage value along the sine wave and thereby adjusting the effective length of the LED string to the instantaneous voltage of the line (or supply voltage). The mains or other external source is coupled to a rectifier circuit (D1 through D4 and Cᵢₙ). This driver circuit may be generally referred to herein as a zero energy storage (ZES) driver circuit. Additional details of ZES driver circuitry can be found in the previously incorporated U.S. application Ser. No. 13/229,611. According to some such example embodiments, all or at least a part of the ZES driver circuit can be integrated with the LED(s) into an LED device.

There are a number of ways in which a monolithic approach as described herein can be carried out. For instance, in one example embodiment some or all of the ZES driver circuit componentry is integrated into an LED device by, for example, fabricating the switches (that are in parallel with the light emitting diodes) and passive components around the switches in the same structuring process that is used to create the LEDs. In such an example embodiment, all the integrated components of the circuit would be made out of the same semiconductor material. For example, for blue, green, phosphor-converted white LEDs, the LEDs and ZES driver circuit componentry can be implemented with indium gallium nitride (InGaN). Alternatively, for red, yellow, amber LEDs, the LEDs and ZES driver circuit componentry can be implemented with indium gallium aluminum phosphide (InGaAlP).

Numerous other suitable semiconductor materials may be used, depending on the desired LED colors and target application(s) of the lighting circuit. For instance, while some embodiments provided herein can be implemented with inorganic semiconductor materials as described above, organic materials may be used as well to provide so-called organic LED (OLED) lighting devices having driving circuit integrated into the OLED device. Here the light emitting material as well the transistors and other electronic components of the circuit would be made out of organic material (e.g., conductive and insulating polymers, etc). As will be appreciated in light of this disclosure, the claimed invention is not intended to be limited to any particular materials systems.

In some embodiments, the control circuit can be implemented with a microcontroller programmed or otherwise configured to control the switches as explained herein or as otherwise desired. In one specific example embodiment, the control circuit can be implemented as shown in FIG. 1b and includes an operational amplifier circuit, a power supply circuit to supply power to the operational amplifier circuit, a voltage reference circuit coupled to an optional harmonic distortion control circuit, and an optional frequency stabilization circuit. The power supply circuit may be a known DC power supply circuit configuration and, in some embodiments, may supply power, either directly or indirectly, from the mains or other voltage source. As can be further seen, the voltage reference circuit is configured to provide a voltage that is based on a fraction of the voltage provided by the voltage source (mains, or rectified output of mains, etc). In some embodiments, this fraction may be adjustable, thus enabling variations in the current through the string of LED(s), and therefore average power, of the system. This fractional voltage is provided to the harmonic distortion control circuit, which couples that signal to the non-inverting input of operational amplifier circuit. The harmonic distortion control circuit may also provide an additional DC component to the positive power input of the operational amplifier circuit to compensate for voltage drops in the voltage source, which may improve the power factor and reduce harmonic distortion of the system.

The output of the current monitor circuit (e.g., Rₛₑₙₛₑ, or some other suitable sense circuit), which monitors current flow through LEDs in the plurality of groups of LEDs, is coupled through the frequency stabilization circuit to the inverting input of the operational amplifier circuit. The operational amplifier circuit is configured to maintain a balance between the monitored LED current flow and the input voltage from the voltage source by adjusting the control signal that it provides to the switches (sw1 through swN) shown in FIG. 1a. The frequency stabilization circuit is configured to adjust the frequency response of the operational amplifier circuit to avoid undesirable oscillations. In some example such embodiments, the frequency stabilization circuit may include a resistor-capacitor (RC) network and the current monitor circuit is a resistor as shown in FIG. 1a.

One specific example embodiment provides an LED device, the LED device including an LED chip on an LED chip carrier housed in an LED package, wherein the LED chip carrier contains the electronic components of the ZES driver circuitry. The LED chip can be, for instance, a thin-film chip wherein epitaxial layers are transferred from a growth substrate to a chip carrier. Subsequently, the growth substrate can be removed or, alternatively, can also remain on the chip carrier (e.g., sapphire flip-chip). The epitaxial layer can be laterally divided into two or more pixels (multi-pixel thin-film LED chip) that are electrically connected in series by suitable conductors provided by additional process steps. A pixel is generally the smallest light emitting unit within the packaged device that can be considered an LED from an electrical point of view. In one specific example embodiment, the chip carrier is implemented with silicon and includes the electronic components of the ZES driver circuitry, such as the switches shown in FIG. 1 (e.g., transistors and necessary/auxiliary electronic components like resistors and diodes around the transistors) that control the LED groups, in an integrated way. To this end, the switches can be connected to the LED pixels in such a way that each pixel forms a group or that more than one pixel in series connection form a group. This electrical connection can be formed during the transfer process of the epitaxial layers to the ZES driver containing chip carrier. Alternatively, only mechanical attachment is done during bonding and electrical connection is performed separately, for example, by bond wires. The device resulting from the integration of the LED chip with a chip carrier containing the electronic components of the ZES driver circuitry can then be placed into a suitable package.

A number of advantages of the techniques provided herein will be apparent in light of this disclosure. For instance, in some embodiments, no additional devices or chips around the LEDs are necessary, which saves cost and space for the LED application and allows very compact line powered light engines, with desirable optical properties. Etendue would be less of an issue in case of, for example, LED spot lights as all pixels of the light source can be densely packed into a small area. In addition, an increase of robustness and lifetime may be realized as there are fewer discrete components and fewer interconnects (e.g., solder joints). This also reduces assembly time and cost.

Circuit Architecture

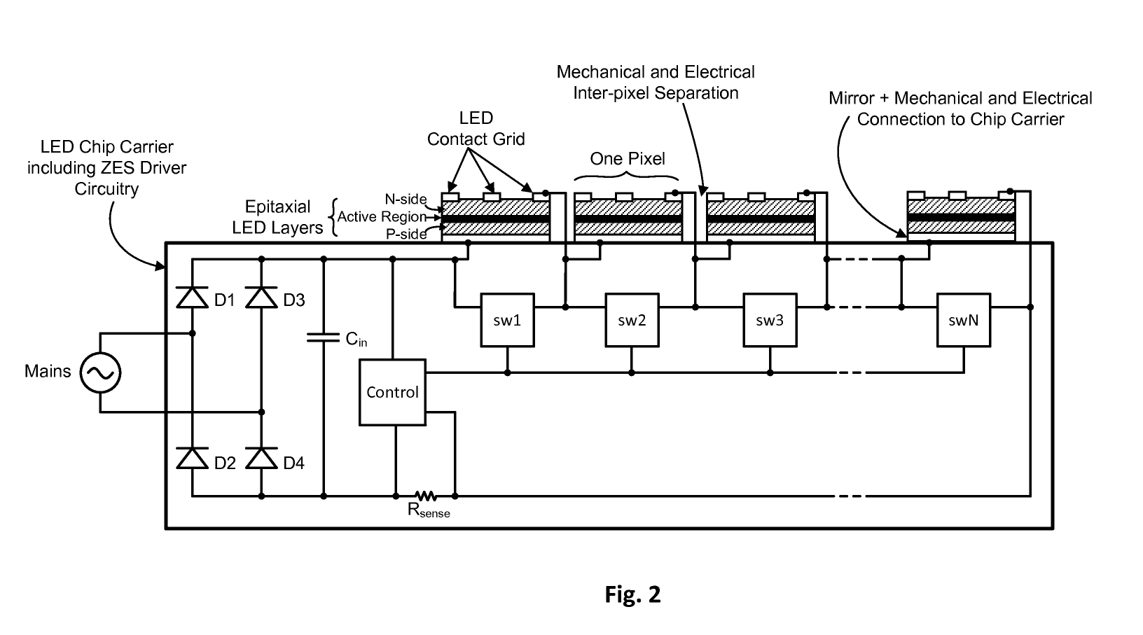

FIG. 2 schematically illustrates a zero energy storage (ZES) driver integrated in an LED chip carrier, in accordance with an embodiment of the present invention. As can be seen, this particular example embodiment includes an LED chip carrier that includes ZES driver circuitry and has a number N of LED epitaxial layers transferred or grown thereon. The carrier chip can be any suitable substrate upon which the LED epitaxial layers can be grown on or transferred to such as silicon, germanium, sapphire, gallium nitride and gallium arsenide substrates. Each LED effectively provides a pixel of the LED device.

The epitaxial LEDs can be implemented using typical semiconductor processing and materials. In the example embodiment shown, an ohmic contact and mirror layer is provided between the epi-LED multilayer structure and substrate to provide mechanical, thermal, and electrical connection to the chip carrier (substrate). Each LED includes an active layer sandwiched between a p-type layer and an n-type layer as shown. Other embodiments may include other layers, such as an adhesion layer and diffusion layers, depending on factors such as materials used and desired performance. The tri-layer of epi material shown may be formed on the substrate in a blanket fashion, and then etched into distinct LEDs; alternatively, the LEDs can be selectively formed on the substrate. In other embodiments, the epi-LEDs are formed on a growth substrate and then transferred to the substrate (chip carrier). While forming the epi-LEDs on the substrate eliminates the need to transfer, it presumes that the LED formation process will not damage or otherwise adversely impact any previously formed componentry on and/or within the substrate (chip carrier). Alternatively, the ZES componentry can be formed after the growth of the epitaxial LED layers on the substrate, in some embodiments.

In one specific example embodiment, the first layer (p-side) is implemented with p-type gallium nitride, the second (active) layer is implemented with undoped indium gallium nitride, and the third layer (n-side) is implemented with n-type gallium nitride. Other example embodiments may include any suitable combinations of column V and/or III-V materials suitable to implement epi-LEDs (e.g., indium aluminum gallium phosphide based LEDs). The claimed invention is not intended to be limited to any particular material system; rather, the monolithic approach provided herein can be implemented with any number of suitable epi-LED materials, depending on factors such as desired device performance, as will be appreciated in light of this disclosure.

As will be further appreciated, the epitaxial layers can be transferred to the ZES chip carrier in waferscale or chip-by-chip. For bonding of the epitaxial layers to the ZES chip carrier in such transfer based embodiments, methods like carrier eutectic soldering, direct bonding or bumping can be used. The ZES componentry can be located, for example, close to the bonding interface or on the opposite side of the chip carrier, electrically connected by vias. Note that the complete ZES circuitry can be integrated into the LED chip carrier, including the bridge rectifier and control circuit (like in the example case of FIG. 2). In this case, the number of pixels can be sufficiently large to directly work at line voltage. This is because there is no constraint, other than cost, given by the ZES circuit on the upper end, using lots of pixels.

The number of LED pixels can range from two to VLine/VfPixel. VLine/VfPixel generally refers to the maximum ever expected line voltage (which might be higher than just the amplitude of the voltage in case of surges on the line, for instance) divided by the minimal forward voltage of a single pixel at nominal current (consider, for example, production spread, temperature and aging over life). The number of groups can vary between two and VLine/VfPixel. The number of pixels in each group may be chosen to be the same for all groups within a particular circuit realization for simplicity reasons, but this is not mandated by the operating principle of the ZES topology provided herein. Other embodiments may have a different number of pixels in one or more of the groups. As can be further seen, there is a mechanical and electrical separation provided between pixels, and a mechanical and electrical connection to the chip carrier. As can be seen with further reference to FIG. 2, the pixel serial connection can be done with vertical LED pixels, wherein an n-side contact of one LED is connected to the p-side of the next pixel. In this particular example embodiment of the present invention, the p-side is connected mechanically to the chip carrier. In another embodiment, this can be the n-side.

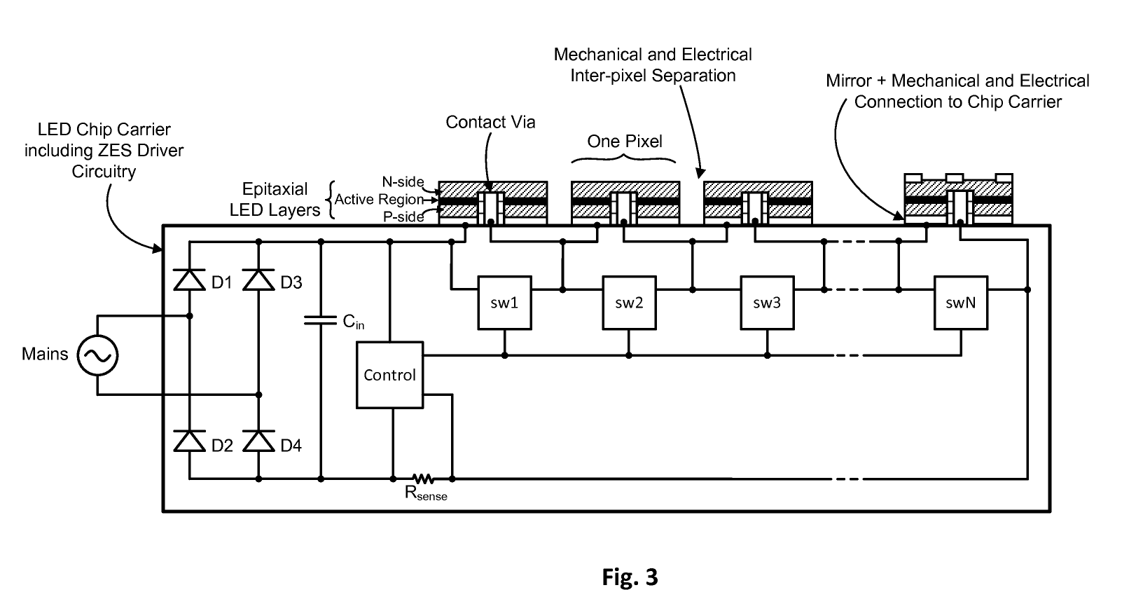

FIG. 3 schematically illustrates a ZES-driver integrated in an LED chip carrier, in accordance with another embodiment of the present invention. In this example case, the pixel serial connection can be done with UX:3-based LED pixels, wherein both contacts are located on one side of the active region and the n-contact of one pixel is connected to p-contact of the next pixel at that side. The serial connection can be, for instance, located in the LED chip (e.g., provided by conductive layers deposited during the LED chip processing) or inside the ZES chip carrier. As can be seen in FIG. 3, a contact via is provisioned in such cases to provide access to the n-side of the epi-LED, and no n-side contact grid is needed. OSRAM Opto Semiconductors' UX:3 chip technology employs thin-GaN technology which generally employs a metallic mirror below its active layer and a well-defined scattering surface for optimized light extraction. In addition to a lateral serial connection of the pixels (or alternatively to such a serial connection), epitaxial stacks of more than one active LED structures (stacked LEDs) can also be used, in some embodiments.

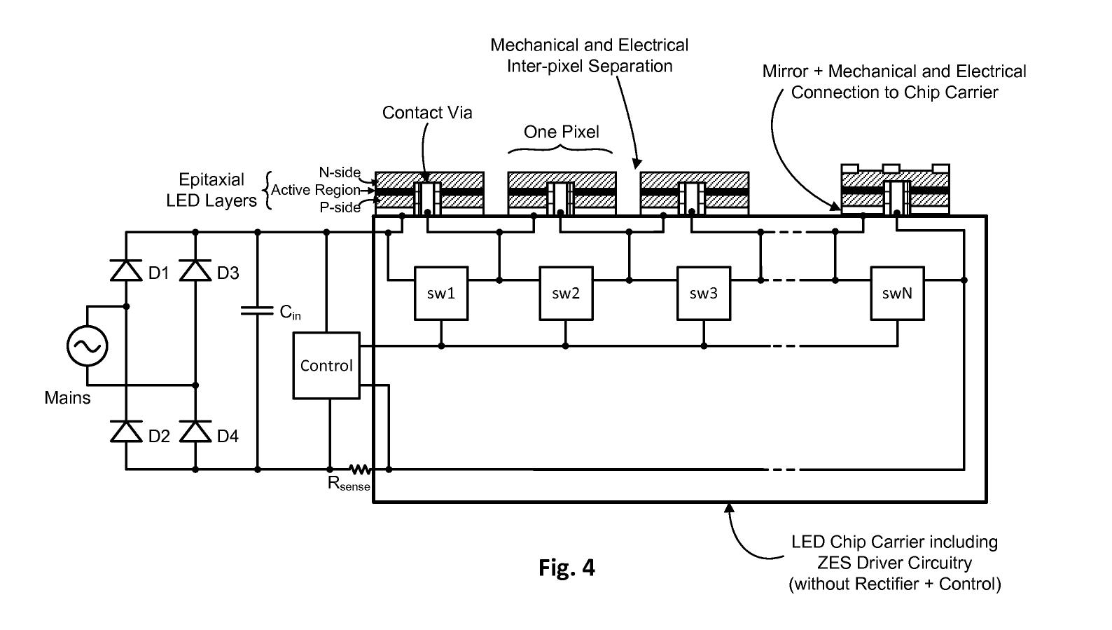

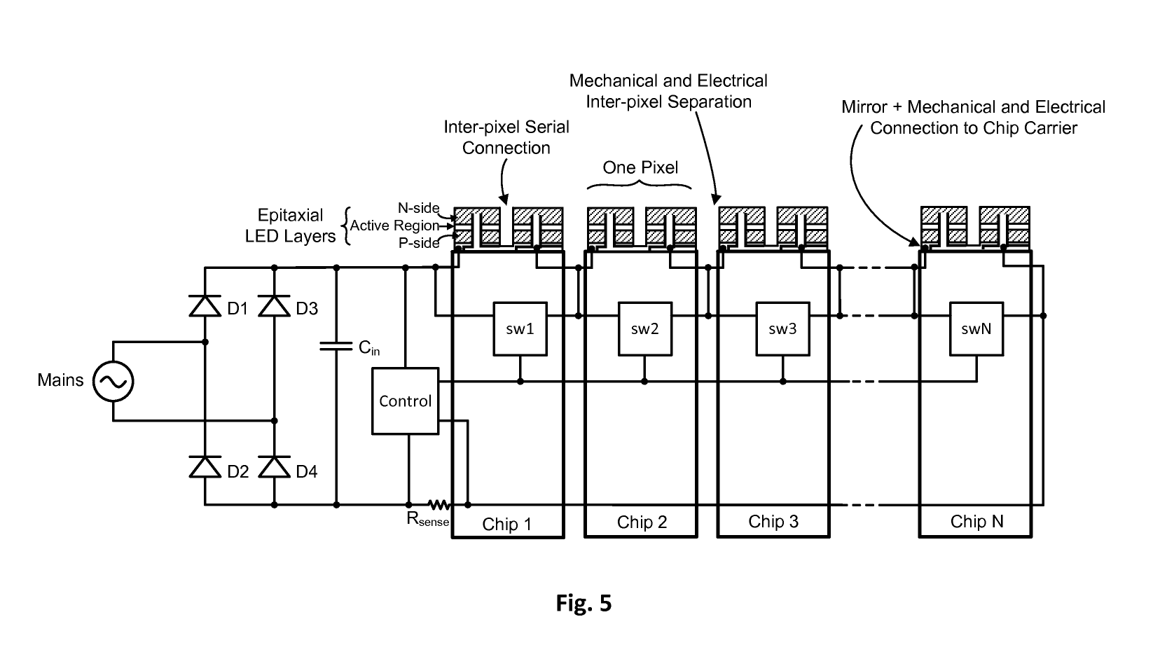

FIG. 4 schematically illustrates a ZES-driver integrated in an LED chip carrier, in accordance with another embodiment of the present invention. In this example case, the pixelated LED chip carrier only includes the controllable switches according to the number of pixel groups on the chip. The bridge rectifier and control circuit componentry can be added externally and the pixels in series connection needed for the given line voltage can be located on just one chip as shown in FIG. 4, or on a number (N) of different chips as shown in the example embodiment of FIG. 5. In this latter example case, the chips are connected in a string by three electrical connections. Therefore each chip has at least three electrical terminals or other means of electrical connections: p-side and n-side of pixel group and control (the return of the end-of-the-string as shown in FIG. 5 may add an additional two electrical connections, in accordance with some embodiments).

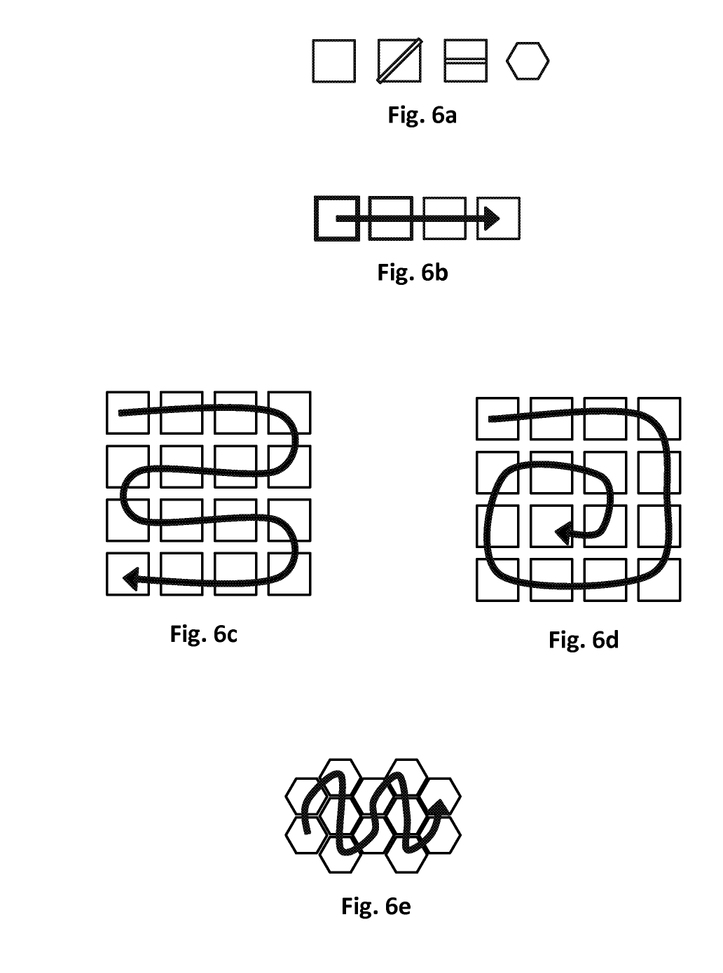

The form of the pixels can be, for example, square, rectangular, triangular, and hexagonal as shown in FIG. 6a, although other less efficient shapes can be used as well (e.g., circles, ovals, etc). The lateral arrangement of the pixels connected in series on a chip carrier can be, for example, line-by-line as shown in FIG. 6b, or just one line as shown in FIG. 6c, or a spiral as shown in FIG. 6d or other desired shapes such as shown in FIG. 6e. As will be appreciated, a spiral shape is particularly advantageous for spot-like (non-linear) light sources, if so desired for a given application.

Packaging

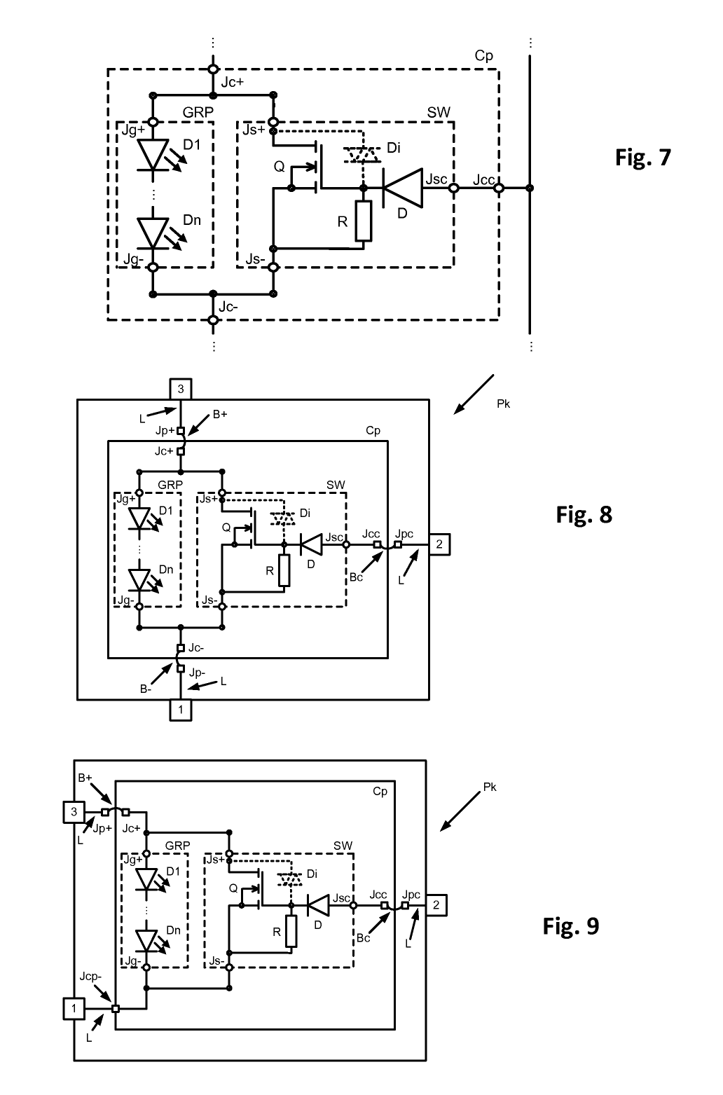

FIG. 7 shows the circuit diagram of a single chip Cp similar to those shown in FIG. 5, except that the end-of-the-string is not routed through the chip, in accordance with an embodiment of the present invention. As can be seen, the chip comprises a group GRP of pixels D1 through Dn which is connected to its associated switch SW. The chip has three electrical connections to the surrounding circuitry: Jc+ on the p-side of pixel group, Jc− on the n-side of pixel group, and to a control circuit via Jcc.

The controllable switch SW in this example embodiment is made of a transistor Q, a diode D and a resistor R. As the voltage across the transistor is limited by the maximum forward voltage across all the pixels of the group to which the corresponding switch is connected, a low-voltage (e.g., 5 volts or less) will be sufficient in most applications. In line voltage applications, the diodes however will need to be able to block the high voltages and therefore typically high-voltage diodes can be used in such cases. FIG. 7 also shows a diode for alternating current (or so-called diac) Di.

The optional device Di can be used to limit the drain-gate-voltage of the transistor Q in case of a failure where, for example, one of the pixels or one of its interconnects fails open. Without this optional diac D1, a high voltage across the group GRP may cause the transistor Q to fail due to the high voltage or a significant dissipation of power which eventually may lead to an open circuit and the complete light engine would fail to emit any light. Thus, by including the diac, the transistor can be turned on in such a failure and basically shunt the defective group, leading to a still operating light engine. The feature of increased fault tolerance is particularly favorable, for instance, in line power applications where hundreds or even more pixels are connected in series.

In other embodiments, instead of a diac Di, a thyristor-based circuitry or even a resistor may be integrated instead to achieve similar benefits. Circuits comprising latching devices, like diacs or thyristors may be generally favored over a simple resistor or other non-latching circuits, because latching circuits and devices typically have a low drop voltage across them after they have been latched which greatly reduces the amount of power that would otherwise be dissipated in the transistor Q. As will be appreciated in light of this disclosure, numerous switching schemes other than the example shown in FIG. 7, including various transistor arrangements using high-side drivers or opto-couplers, can be used as well. With reference to FIGS. 7-9, 12, and 13, note that dashed boxes are generally used to delineate or reference circuit and functional blocks, whereas solid boxes are generally used to delineate or reference mechanical parts.

In another embodiment of the present invention, each single chip is packaged to a device, such as a surface-mount device (SMD). Such a device can have at least 3 pins, as depicted in the example embodiment of FIG. 8. The package Pk has three pins 1, 2 and 3. As can be further seen, the electrical connection from the chip to the leadframe L of the package is done through bond wire B+, B− and Bc connecting the bond pads Jp+ and Jc+, Jp− and Jc−, Jpc and Jcc, respectively. As will be appreciated in light of this disclosure, several of these packaged devices can be soldered onto a printed circuit board and form the light engine, in accordance with an embodiment.

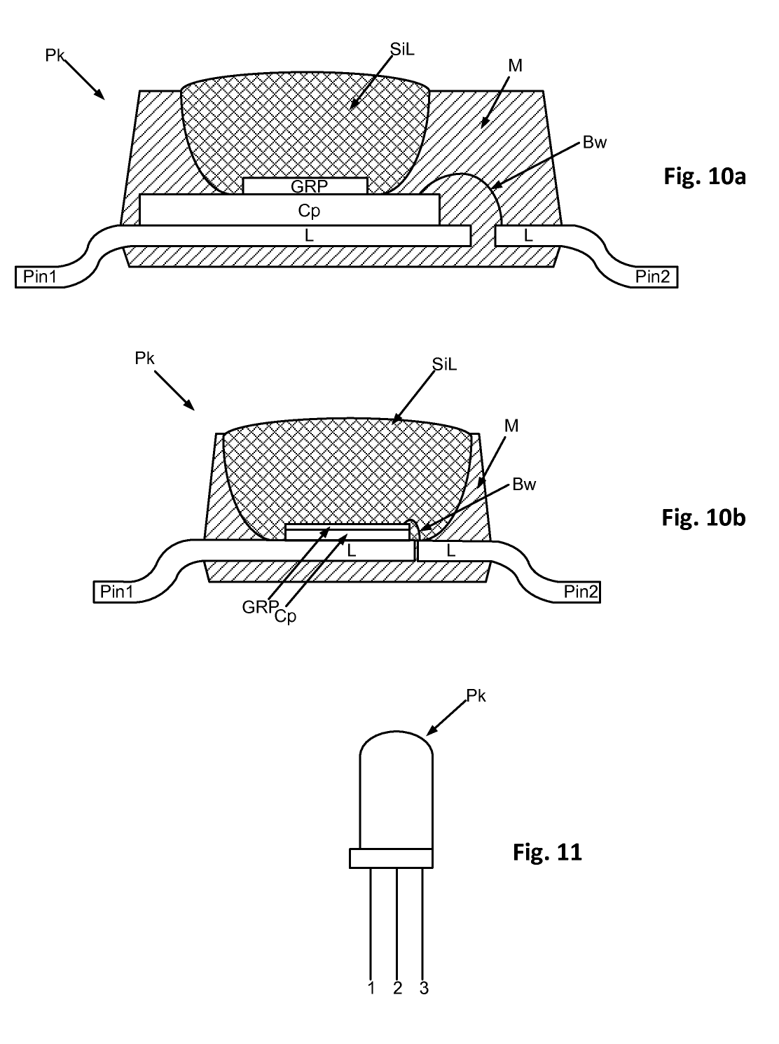

FIG. 9 shows a similar SMD package like the one shown in FIG. 8, but in this example case, the package Pk is more like an SOT23 package. A single chip carrier Cp is mounted onto the leadframe to mechanically hold the chip in place and to establish an effective thermal path for cooling of the chip carrier. As the chip carrier Cp is soldered with electrical conducting solder to the leadframe (in accordance with some embodiments), the electrical connection Jcp− is formed. Therefore only two bond wires B+ and Bc are present in the package in this example configuration. This can also be seen in the cross-sectional side view of the example embodiment of FIG. 10a. Table 1 defines the various labels used in FIG. 10a, according to one specific such embodiment.

TABLE 1
Example Implementation

| Label | Feature |
|---|---|
| GRP | Thin-film chip comprising a group of pixels |
| Cp | Chip carrier |
| L | Leadframe |
| M | Mold compound (plastics) |
| SiL | Lens made of transparent silicone elastomer |
| Pin1, | Pins of package created by the leadframe |
| Pin2 | sticking out of mold compound (Pin3 not |
| | shown) |

Numerous other suitable configurations and materials will be apparent in light of this disclosure, and the claimed invention is not intended to be limited to any particular set of configurations or materials.

FIG. 10b illustrates a cross-sectional side view of another SMD package based embodiment which is very similar to the example embodiment shown in FIG. 10a. However, note that the thin-film chip GRP has the same lateral dimensions as the chip carrier Cp and the bondwire Bw is completely inside the volume of the transparent silicone elastomer (or other suitable such material).

FIG. 11 shows a side view of a radial LED device in a leaded package Pk, configured in accordance with an embodiment of the present invention. The electrical circuit inside the package can be configured, for instance, in an identical or otherwise similar fashion to the one shown FIG. 9.

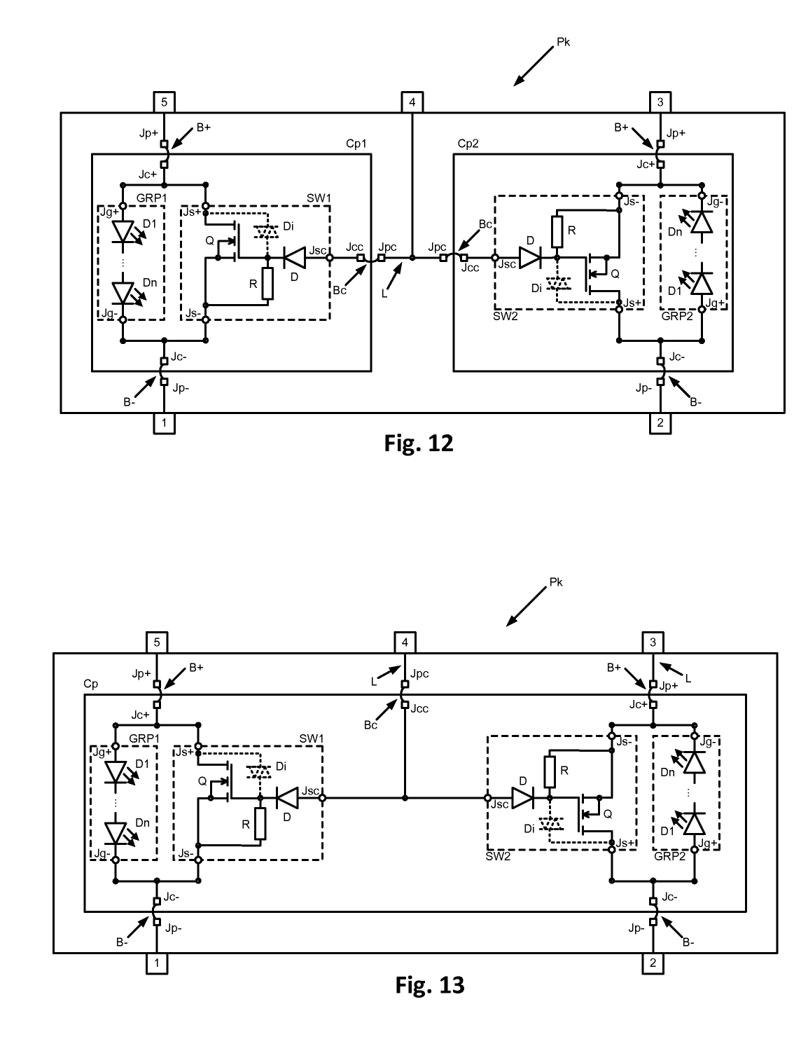

FIG. 12 shows a package Pk including two chip carriers Cp1 and Cp2, in accordance with an embodiment of the present invention. An SOT23-5 like package having five pins can be used for this purpose, in some example cases. Note the control pin can be shared by the two chip carriers. As can be seen, identical references to functionally identical objects are used for the sake of simplicity, although any number of variations and other embodiments will be apparent in light of this disclosure.

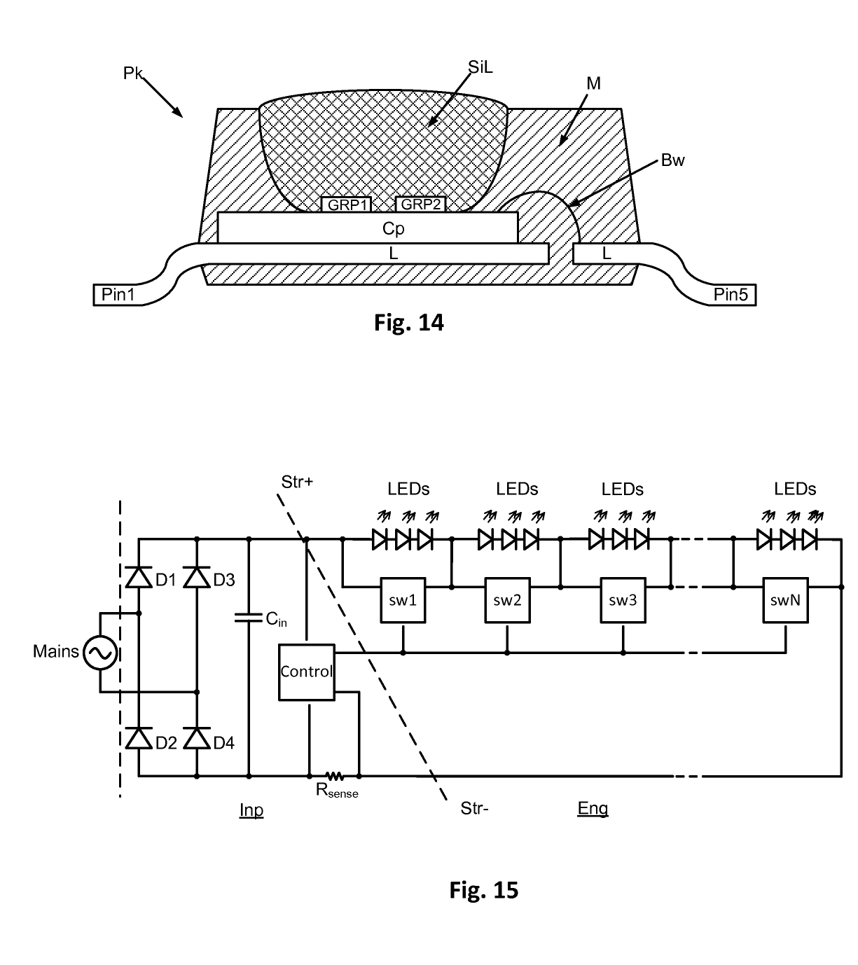

FIG. 13 shows a package Pk holding a single chip carrier Cp which comprises of two switches SW1 and SW2, in accordance with an embodiment of the present invention. In addition the chip carrier carries two groups of pixels GRP1 and GRP2. From an applications stand point, a user might not be able to tell the difference between the devices shown in FIGS. 12 and 13. Nevertheless there may be a significant difference from a device manufacturing point of view. The advantage of the example arrangement according to FIG. 12 might be to possibly geometrically place the two groups closer together. On the other hand, the chip design in the arrangement shown to FIG. 13 might be more difficult to realize as the electrical potentials on the chip might be significant depending on where in the LED string the two groups are located. FIG. 14 shows the cross-sectional view of an LED device configured in accordance with an embodiment of the present invention which is similar to that shown in FIG. 13, except that the connection Jc− to Jp− leading to pin 1 is accomplished by soldering of the chip carrier Cp to the leadframe, an therefore only one bond wire B− is present in the LED device. Further connections are not shown, but may also be included. Numerous variations will be apparent in light of this disclosure.

Some implementations of ZES circuit topology show significant brightness difference between the pixels at the beginning of the LED string (close to Str+ in FIG. 15) compared to the end of the LED string (close to Str− in FIG. 15), assuming identical pixels and numbers of pixels per group. In accordance with an embodiment of the present invention this brightness differential can be significantly alleviated by packaging one or more groups from the beginning of the LED string with one or more groups from the end of the LED string into a single package, because to the close proximity of the groups within the package the brightness differences get averaged over space and thereby lead to a more homogeneous brightness impression in the viewer's eyes.

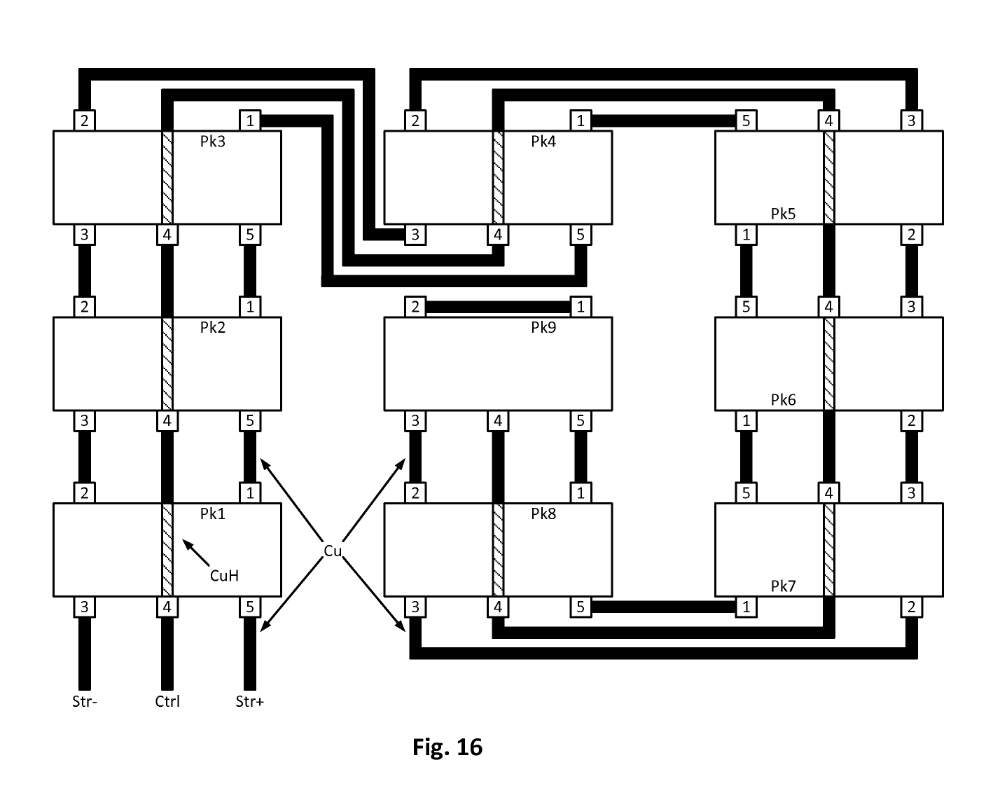

FIG. 16 shows the top view of a printed circuit board (PCB) populated with devices Pk1 through Pk9, each of which can be implemented, for example, according to FIGS. 8 and/or 9. The PCB effectively realizes the Eng part of the circuit shown in FIG. 15, and the input part Inp, which includes the rectifier and the control circuitry, can be realized on a different PCB wherein both PCBs can be connected through three wires with each other. The pin-out (arrangement of pins on the perimeter and of the device and the assignment of electrical functionality to the pins) shown in the example embodiments of FIGS. 12 and 13 come with the advantage that for a realization of a light engine according to FIG. 16, a single-sided PCB can be utilized as there may be no need to realize non-conducting crossing of copper traces on the PCB. Thus, a snail-house-like arrangement of the copper traces can be provided in the PCB layout, as shown in the example embodiment of FIG. 16. As can be seen with further reference to FIG. 16, copper traces are designated as Cu where visible, and as CuH where hidden underneath an LED device.

Numerous variations of the example embodiments depicted will be apparent in light of this disclosure. For example, the type of LEDs can be different from chip to chip, especially the emission color of the chip can vary (e.g., R/G/B or greenish-white/red). If the final emission color of the chips is given by a wavelength conversion element, there can be different conversion elements (e.g., different emission colors) from chip to chip and/or from pixel group to pixel group and/or from pixel to pixel. Further note that ESD protection functionality that normally has to be added as a discrete device may already be included in the integrated chip just by the ZES driver circuitry. For instance, in the example embodiment shown in FIG. 6, the body diode of the MOSFET Q may act as an ESD protection device.

Numerous variations and embodiments will be apparent in light of this disclosure. For example, one embodiment of the present invention provides a semiconductor device that includes a chip carrier, a light emitting diode (LED) formed on or bonded to the chip carrier, and a switch formed on or in the chip carrier and operatively coupled across the LED, and configured to regulate current through the LED in response to a control signal. In some cases, the device further includes a control circuit for providing the control signal for controlling the switch. In one such case, the control circuit includes a sense circuit for sensing current flowing through the LED. In some cases, the device further includes a rectifier circuit configured to receive a voltage source and to provide a rectified voltage across the LED. In some cases, the LED is included in a serially connected string of LEDs, and the switch is connected across multiple LEDs in the string. In some such cases, the device further includes a number of additional switches, each additional switch connected across a different set of multiple LEDs in the string. In some cases, the LED comprises a thin-film LED chip. In some cases, the LED comprises a sapphire flip-chip. In some cases, the LED includes an active layer sandwiched between a p-type layer and an n-type layer, and a contact via configured to allow both n-side and p-side contacts to be located on one side of the active layer. In some cases, the device further includes a mirror layer between the chip carrier and the LED. In some cases, the device further includes an integrated circuit package that contains the chip carrier including the LED and switch. In some such cases, the integrated circuit package has three or more leads and is one of a small-outline transistor (SOT) package, a surface mount package (SMP), or a radial LED device package. In other such cases, the integrated circuit package houses multiple chip carriers, each chip carrier carrying one or more LEDs and configured with one or more switches for controlling LED current flow. In other such cases, the chip carrier is the only chip carrier in the integrated circuit package, the chip carrier including a plurality of switchable LED circuits. In one such case, each of the switchable LED circuits is associated with p-contact lead, an n-contact lead, and a control lead. Another example embodiment includes a system comprising two or more of the semiconductor devices as various defined in this paragraph and operatively coupled to provide a serially connected string of LEDs. In one such system, the two or more devices are populated on a printed circuit board. Another example embodiment provides a light engine that includes the system.

Another embodiment of the present invention provides a semiconductor device that includes a chip carrier, and a plurality of light emitting diodes (LEDs) formed on or bonded to the chip carrier and serially connected, wherein the LEDs comprise an active layer sandwiched between a p-type layer and an n-type layer, said layers being laterally structured into mechanically and electrically separated semiconductor pixels that are connected in series. The device further includes a plurality of switches formed on or in the chip carrier, each switch operatively coupled across a different subset of the LEDs and configured to regulate current through that subset in response to a control signal. The device further includes an integrated circuit package that contains the chip carrier including the LEDs and switches. In some cases, the device further includes at least one of: a mirror layer between the chip carrier and each of the LEDs; a control circuit for providing control signals for controlling the switches, wherein the control circuit includes a sense circuit for sensing current flowing through the LEDs; and/or a rectifier circuit configured to receive a voltage source and to provide a rectified voltage across the LEDs. In some cases, at least one of the LEDs comprises a thin-film LED chip. In some cases, at least one of the LEDs includes an active layer sandwiched between a p-type layer and an n-type layer, and a contact via configured to allow both n-side and p-side contacts to be located on one side of the active layer. In some cases, the integrated circuit package houses multiple chip carriers, each chip carrier carrying one or more LEDs and configured with one or more switches for controlling LED current flow. In some cases, the chip carrier is the only chip carrier in the integrated circuit package, the chip carrier including a plurality of switchable LED circuits, and each of the switchable LED circuits is associated with p-contact lead, an n-contact lead, and a control lead.

Another embodiment of the present invention provides a lighting system configured with an integrated circuit including one or more light emitting diodes (LEDs) and switching circuitry for controlling current flow through the LEDs in response to one or more brightness regulating control signals, the system further configured for coupling directly to a rectified voltage source. In some cases, the one or more LEDs comprise thin-film LED chips formed on a carrier chip housed in an integrated circuit package.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

1. A semiconductor device, comprising:
a chip carrier;
a light emitting diode (LED) formed on or bonded to the chip carrier; and
a switch formed on or in the chip carrier and operatively coupled across the LED, and configured to regulate current through the LED in response to a control signal.

2. The device of claim 1 further comprising a control circuit for providing the control signal for controlling the switch.

3. The device of claim 2 wherein the control circuit includes a sense circuit for sensing current flowing through the LED.

4. The device of claim 1 further comprising a rectifier circuit configured to receive a voltage source and to provide a rectified voltage across the LED.

5. The device of claim 1 wherein the LED is included in a serially connected string of LEDs, and the switch is connected across multiple LEDs in the string.

6. The device of claim 5 further comprising a number of additional switches, each additional switch connected across a different set of multiple LEDs in the string.

7. The device of claim 1 wherein the LED comprises a thin-film LED chip.

8. The device of claim 1 wherein the LED comprises a sapphire flip-chip.

9. The device of claim 1 wherein the LED comprises:
an active layer sandwiched between a p-type layer and an n-type layer; and
a contact via configured to allow both n-side and p-side contacts to be located on one side of the active layer.

10. The device of claim 1 further comprising a mirror layer between the chip carrier and the LED.

11. The device of claim 1 further comprising an integrated circuit package that contains the chip carrier including the LED and switch.

12. The device of claim 11 wherein the integrated circuit package has three or more leads and is one of a small-outline transistor (SOT) package, a surface mount package (SMP), or a radial LED device package.

13. The device of claim 11 wherein the integrated circuit package houses multiple chip carriers, each chip carrier carrying one or more LEDs and configured with one or more switches for controlling LED current flow.

14. The device of claim 11 wherein the chip carrier is the only chip carrier in the integrated circuit package, the chip carrier including a plurality of switchable LED circuits.

15. The device of claim 14 wherein each of the switchable LED circuits is associated with p-contact lead, an n-contact lead, and a control lead.

16. A system comprising two or more of the semiconductor devices defined in claim 1 operatively coupled to provide a serially connected string of LEDs.

17. The system of claim 16 wherein the two or more devices are populated on a printed circuit board.

18. A light engine comprising the system of claim 16.

19. A semiconductor device, comprising:
a chip carrier;
a plurality of light emitting diodes (LEDs) formed on or bonded to the chip carrier and serially connected, wherein the LEDs comprise an active layer sandwiched between a p-type layer and an n-type layer, said layers being laterally structured into mechanically and electrically separated semiconductor pixels that are connected in series;
a plurality of switches formed on or in the chip carrier, each switch operatively coupled across a different subset of the LEDs and configured to regulate current through that subset in response to a control signal; and
an integrated circuit package that contains the chip carrier including the LEDs and switches.

20. The device of claim 19 further comprising at least one of:
a mirror layer between the chip carrier and each of the LEDs;
a control circuit for providing control signals for controlling the switches, wherein the control circuit includes a sense circuit for sensing current flowing through the LEDs; and
a rectifier circuit configured to receive a voltage source and to provide a rectified voltage across the LEDs.

21-26. (canceled)
